(19) United States
(12) Patent Application Publication
(10) Pub. No.: US 2011/0316201 A1
(43) Pub. Date: Dec. 29, 2011

(54) Wafer Level Packaging Using Blade Molding

(75) Inventors: Lin-Chih Huang, Wuri Township (TW); Jing-Cheng Lin, Hsin-Chu (TW); Wen-Chih Chiou, Miaoli (TW); Shin-Puu Jeng, Hsin-Chu (TW); Chen-Hua Yu, Hsin-Chu (TW)

(73) Assignee: Taiwan Semiconductor Manufacturing Company, Ltd., Hsin-Chu (TW)

(21) Appl. No.: 12/822,880

(22) Filed: Jun. 24, 2010

(51) Int. Cl. B06B 1/00; H01L 21/56; B29C 45/07

(52) U.S. Cl. 264/442; 425/219; 264/272.17

(57) ABSTRACT

In accordance with an embodiment, a molding apparatus comprises a screen having a planar top surface; a recess in the screen and extending below the planar top surface; a blade capable of traversing the planar top surface; and a molding compound applicator. Another embodiment is a method for molding. The method comprises providing a substrate in a confined volume with an open top surface, applying molding compound in the confined volume, and traversing the open top surface with a blade thereby forming the molding compound to have a planar surface that is co-planar with the open top surface. The substrate has at least one semiconductor die adhered to the substrate.

### TECHNICAL FIELD

The present disclosure relates generally to semiconductor packaging and, more particularly, to wafer level packaging using blade molding.

### BACKGROUND

As the demand for smaller electronic devices has grown over recent years, there has grown a need for smaller and more creative packaging techniques of semiconductor dies or integrated circuits. One of the techniques that has been created is what is known to be a wafer level package (WLP). Generally, this technique involves packaging semiconductor dies at the wafer level before each die is singulated into its own, separate package.

A process for creating a WLP generally involves applying a molding compound, or encapsulant, to a wafer before the dies are singulated. In some processes, a wafer will be adhered to a carrier substrate by an adhesive. Then, the carrier, adhesive, and wafer combination will be placed in a mold. A molding compound is applied to the wafer. To ensure proper coverage of the molding compound, heat is applied by the mold to make the molding compound more pliable. The mold then applies a compressive force to the molding compound and, thereby, to the carrier, adhesive, and the wafer, to obtain a planar encapsulant and proper coverage.

These processes that apply heat and use compressive force suffer from disadvantages. By applying heat to the structure to make the molding compound pliable, the adhesive may also become pliable. When the adhesive becomes pliable, it may overflow from around the periphery of the wafer when the compressive force is applied to the structure. The overflow may then cause a non-uniform force on the wafer, particularly near the edge of the wafer. Cracking of the wafer then may result which may lead to defective dies. Accordingly, there is a need in the art to overcome these stated deficiencies.

### SUMMARY

In accordance with an embodiment, a molding apparatus comprises a screen having a planar top surface; a recess in the screen and extending below the planar top surface; a blade capable of traversing the planar top surface; and a molding compound applicator.

Another embodiment is a method for molding. The method comprises providing a substrate in a confined volume with an open top surface, applying molding compound in the confined volume, and traversing the open top surface with a blade thereby forming the molding compound to have a planar surface that is co-planar with the open top surface. The substrate has at least one semiconductor die adhered to the substrate.

A further embodiment is a method for molding. The method comprises providing a substrate in a recessed portion of a screen. The recessed portion extends away from a top surface of the screen, and the substrate has at least one die attached to the substrate. The method also comprises applying molding compound in the recessed portion and crossing the top surface with a blade such that the molding compound in the recessed portion has a surface that is co-planar with the top surface of the screen

### BRIEF DESCRIPTION OF THE DRAWINGS

For a more complete understanding of the present embodiments, and the advantages thereof, reference is now made to the following descriptions taken in conjunction with the accompanying drawings, in which:

FIG. 1 is a cross-sectional view of an apparatus for applying a molding compound using blade molding according to an embodiment;

FIG. 2 is a three-dimensional view of the apparatus in FIG. 1; and

FIGS. 3A through 3C are various stages of a method of operation to apply molding according to another embodiment.

### DETAILED DESCRIPTION OF ILLUSTRATIVE EMBODIMENTS

The making and using of the present embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosed subject matter, and do not limit the scope of the different embodiments.

Embodiments will be described with respect to a process for wafer level packaging and an apparatus for use in the process. Other embodiments may also be applied, however, to other situations where a molding compound or encapsulant is applied during packaging.

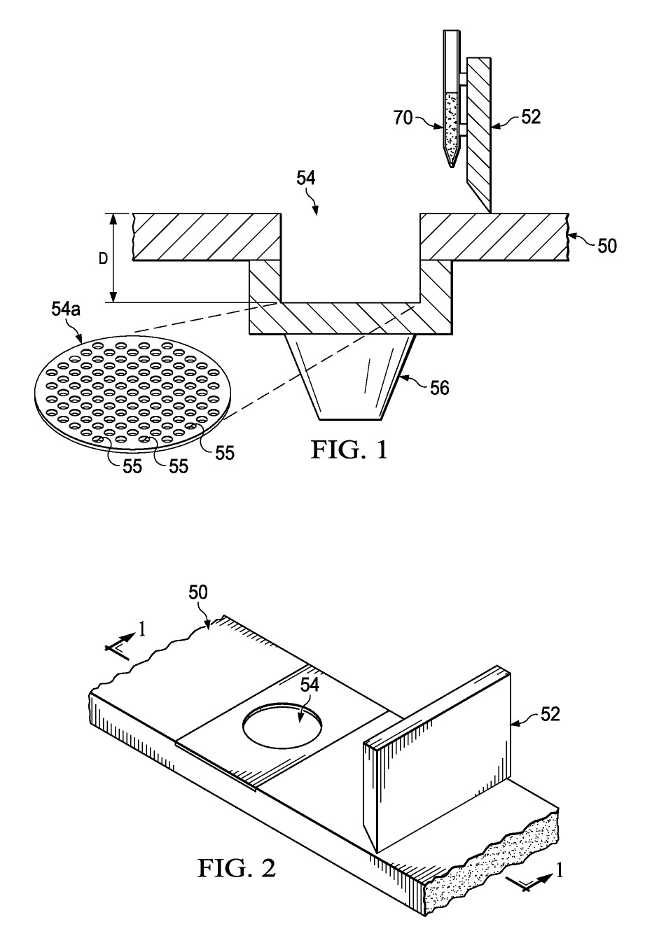

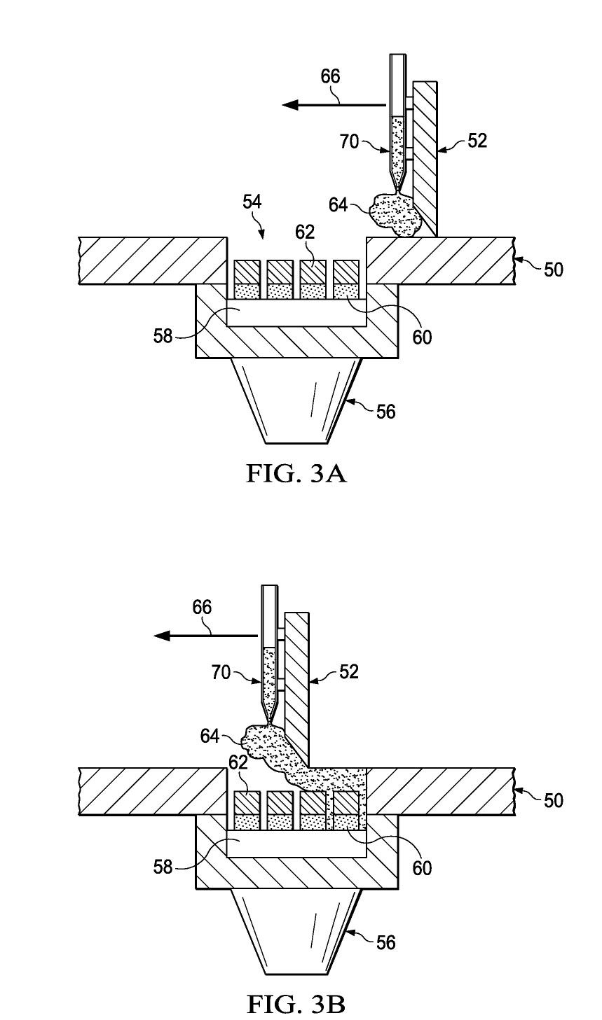

With reference now to FIG. 1, there is shown a cross-sectional view of an apparatus for applying a molding compound to form a WLP using blade molding. The apparatus comprises a screen 50, a blade 52, a recessed portion 54, and a vacuum system 56. The screen 50 is a planar surface with the recessed portion 54 formed therein, and may be made of, for example, stainless steel. The recessed portion 54 may have a circular areal opening in the top surface of the screen 50, as shown in the three-dimensional view of FIG. 2, and sidewalls of the recessed portion 54 may extend in a direction perpendicular to the top surface of the screen 50 to a depth D. The depth D of the recessed portion 54 may be adjustable. Other shapes and/or configurations of the screen 50 and/or the recessed portion 54 are also considered within the scope of other embodiments.

The vacuum system 56 is attached to the recessed portion 54 in a lower section of the recessed portion 54. When the apparatus is in use, the vacuum system 56 may apply suction to a carrier substrate placed in the recessed portion 54 thereby securing the carrier substrate. For example, as shown in inset, the bottom surface 54a of the lower portion of the recessed portion 54 may comprise openings 55 whereby a vacuum or suction may be applied in the recessed portion 54. The vacuum system 56 is merely one example of a means to secure a carrier substrate in the recessed portion 54, and other modes of securing the carrier substrate are considered within the scope of other embodiments. For example, a mechanical force may be applied to a carrier substrate, such as by a clamp in the recessed portion 54.

The apparatus also comprises the blade 52 that is capable of traversing the screen 50 and, thereby, the recessed portion 54. The blade 52 comprises a beveled edge proximate the screen 50. The blade 52 may also comprise a molding compound injector or sprayer mounted on the blade 52 for applying a molding compound when the apparatus is in use. As an example, FIG. 1 illustrates an injector 70 mounted on the blade 52.

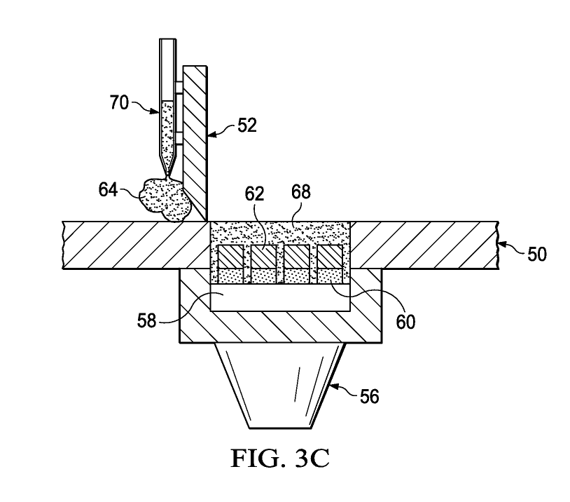

FIGS. 3A through 3C illustrate a method of operation to apply molding using the apparatus described with respect to FIGS. 1 and 2. FIG. 3A illustrates a carrier substrate 58 placed in the recessed portion 54. The carrier substrate 58 has separate dies 62 adhered to the carrier substrate 58 by adhesive strips 60. The dies 62 and adhesive strips 60 may be diced from a wafer adhered to the carrier substrate 58 before the carrier substrate 58 is placed in the recessed portion. The vacuum system 56 may provide a suction to secure the carrier substrate 58 within the recessed portion 54.

The injector 70, a spray, or other mechanism may supply a molding compound 64 as the blade 52 begins traversing the screen 50 in the direction of the operational arrow 66. The blade 52 scrapes along the top surface of the screen 50 with the beveled edge. Once the beveled edge reaches the recessed portion 54, the beveled edge may force the molding compound 64 into the recessed portion 54 to encapsulate the dies 62 and adhesive strips 60, as shown in FIG. 3B. The molding compound 64 encapsulating the dies 62 and adhesive strips 60 may have a top surface that is co-planar with the top surface of the screen 50. Also, the molding compound 64 may conform to the open volume of the recessed portion 54.

FIG. 3C shows the semiconductor dies 62 and adhesive strips 60 fully encapsulated with the molded molding compound 68. As can be seen from FIG. 3C, the top surface of the molded compound 68 is co-planar with the top surface of the screen 50. Also, if the depth D of the recessed portion 54 is adjustable, the thickness of the molded compound 68 over the dies 62 may be tuned, such as by increasing or decreasing the thickness, to meet design specifications. It is worth noting that the blade 52 may pass over the screen 50 multiple times to fully mold the molded compound 68 to encapsulate the dies 62 and adhesive strips 60. Also, the blade 52 may be capable of operating in many directions parallel to the top surface of the screen 50, and/or the blade may be angled to the operational direction such that it is not perpendicular to the operational direction in a plane parallel to the top surface of the screen 50 to change the angle at which the beveled edge traverses the screen 50. Even further, the beveled edge of the blade 52 may have a dual bevel instead of the single bevel illustrated in the figures.

Once the molded compound 68 fully encapsulates the dies 62 and the adhesive strips 60, the carrier substrate 58 along with the dies 62, adhesive strips 60, and molded compound 68 may be removed from the recessed portion 54 of the screen 50 and placed in an oven to cure, according to acceptable processes. If needed, the screen 50 may be cleaned using ultrasonication to remove any excess molding compound 64. After the molded compound 68 is cured, individual dies 62 may be singulated being fully encapsulated by the carrier substrate 58 and the molded compound 68, according to appropriate methods.

Using these embodiments, heating the molding compound may not be necessary to mold the compound. Thus, the adhesive may remain in a more solid form and support the dies better than when the adhesive is heated. In addition, less, if any, compressive force may be used in molding the compound. These two features, individually or in combination, may make the molding process more robust and prevent die cracking and adhesive overflow.

Although the present embodiments and their advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A molding apparatus comprising:
a screen having a planar top surface;
a recess in the screen and extending below the planar top surface;
a blade capable of traversing the planar top surface; and
a molding compound applicator.

2. The molding apparatus of claim 1, wherein the recess has an adjustable depth in a direction extending from the planar top surface.

3. The molding apparatus of claim 1, wherein the blade comprises a beveled edge proximate the planar top surface.

4. The molding apparatus of claim 1, wherein the molding compound applicator is an injector.

5. The molding apparatus of claim 1, wherein the molding compound applicator is on the blade.

6. The molding apparatus of claim 1 further comprising a securing mechanism near the recess.

7. The molding apparatus of claim 6, wherein the securing mechanism is a vacuum system.

8. A method for molding, the method comprising:
providing a substrate in a confined volume with an open top surface, the substrate having at least one semiconductor die adhered to the substrate;
applying molding compound in the confined volume; and
traversing the open top surface with a blade thereby forming the molding compound to have a planar surface that is co-planar with the open top surface.

9. The method of claim 8 further comprising adjusting a depth of the confined volume, the depth being in a direction extending from the open top surface.

10. The method of claim 8 further comprising securing the substrate in the confined volume.

11. The method of claim 10, wherein the securing the substrate comprises providing a suction to the substrate.

12. The method of claim 8 further comprising curing the molding compound.

13. The method of claim 8, wherein the applying the molding compound includes using an injector.

14. A method for molding, the method comprising:
providing a substrate in a recessed portion of a screen, the recessed portion extending away from a top surface of the screen, and the substrate having at least one die attached to the substrate;
applying molding compound in the recessed portion; and
crossing the top surface with a blade such that the molding compound in the recessed portion has a surface that is co-planar with the top surface of the screen.

15. The method of claim 14 further comprising adjusting a depth of the recessed portion in a direction from the top surface of the screen.

16. The method of claim 14, wherein the blade comprises a beveled edge proximate the top surface of the screen.

17. The method of claim 14, wherein applying the molding compound comprises injecting the molding compound from an injector mounted on the blade.

18. The method of claim 14 further comprising securing the substrate to the recessed portion by providing a suction.

19. The method of claim 14 further comprising curing the molding compound.

20. The method of claim 14 further comprising cleaning the screen using ultrasonication.
